(19) United States
(12) Patent Application Publication
(10) Pub. No.: US 2026/0096014 A1
(43) Pub. Date: Apr. 2, 2026

(54) WIRING BOARD AND VEHICLE DISPLAY DEVICE

(71) Applicant: Nippon Seiki Co., Ltd., Niigata (JP)

(72) Inventor: Terunobu Kobayashi, Niigata (JP)

(21) Appl. No.: 19/321,823

(22) Filed: Sep. 8, 2025

(30) Foreign Application Priority Data
Oct. 1, 2024 (JP) 2024-171903

(51) Int. Cl. H05K 1/02; B60K 35/28; B60R 16/03; H05K 1/18

(52) U.S. Cl. CPC H05K 1/0237; B60K 35/28; B60R 16/03; H05K 1/0218; H05K 1/184; H05K 2201/10022; H05K 2201/10174

(57) ABSTRACT

A wiring board has a high-frequency transmission path and a ground plane, in which a return current flows in the ground plane due to an AC signal through the transmission path. The ground plane is formed with a first cutout portion for an electronic component formed at a position corresponding to an electronic component, and a second cutout portion serving as a slit portion. In a transparent plan view, the first and second cutout portions are arranged such that at least a portion is overlapping. A ground pattern for an electronic component extends in a transmission direction of an AC signal across the second cutout portion serving as a slit portion. Each of a first and second ground planes is electrically connected to the ground pattern of an electronic component by through-conductors, and a bypass path is formed that allows a return current to flow around the second cutout portion.

### TECHNICAL FIELD

The present invention relates to a wiring board, and a vehicle display device or the like mounted in a vehicle such as an automobile.

### BACKGROUND ART

Patent Document 1 discloses a circuit board having a first ground layer, and a second ground layer that functions as an AC ground, which is connected to the first ground layer via a bypass capacitor and allows only an AC noise component to flow to the first ground layer.

As described in paragraph [0031] of Patent Document 1, a cutout portion (generally referred to as a slit) where the ground layer is not formed is provided between the first ground layer and the second ground layer, and the DC potential of each ground layer is isolated by the slit.

In the circuit board of FIG. 4B of Patent Document 1, a signal line that transmits a differential current signal is wired across the slit (cutout portion).

### PRIOR ART DOCUMENT

### Patent Document

Patent Document 1: Japanese Unexamined Patent Application Publication No. 2022-36741

### SUMMARY OF INVENTION

### Technical Problem

As described in Patent Document 1, in a circuit board, when a signal line in an nth layer (where n is a natural number of 2 or more) is wired across a slit (cutout portion) provided in a ground layer, if a high-frequency signal (microwave) is transmitted via the signal line, an eddy current is generated in the signal wiring. As a result of electromagnetic induction caused by the eddy current, a return current (which can be referred to as a “reflected wave” generated in a terminal end portion when the high-frequency signal is regarded as a microwave) is generated in a ground plane (ground surface) provided in an (n-1)th layer, which is one layer below, in a direction opposite to the direction in which the high frequency signal flows.

The return current attempts to flow through the ground plane from a receiving end to a transmitting end of the high-frequency signal. However, the path along the shortest route is blocked by the slit (ground cutout portion) provided in the ground plane. As a result, the return current flows by making a large detour through an unordered current path through which the return current can flow. This causes an increase in unwanted reflections in the return current, leading to waveform distortion.

The transmitted high-frequency signal and the return current are in a paired relationship, and an increase in reflections and waveform distortion in the return current is directly linked to an increase in the characteristic impedance of the transmitted high-frequency signal. An increase in the characteristic impedance in the transmission path of the high-frequency signal causes signal reflections and waveform distortion, which decreases signal quality, and the signal quality may not be ensured within an allowable range in some cases.

Furthermore, the degradation of signal quality also has a significant impact on the electromagnetic compatibility (EMC).

To keep the EMC within a predetermined allowable range, it is important to reduce the adverse effects of external noise on the circuit, and further, to reduce the emission of unwanted electromagnetic waves from the circuit itself acting as a noise source (in other words, to suppress unwanted radiation). However, the increase in reflections and waveform distortion of the high-frequency signal described above causes the emission of unwanted electromagnetic waves to the outside, leading to a decrease in the EMC.

On the other hand, if the slit (ground layer cutout portion) in the ground plane is eliminated, the problem of crosstalk occurs when a different circuit operates, in which the operation of one circuit causes a fluctuation in the potential of the ground plane at the position corresponding to the one circuit, and the fluctuation propagates to another circuit via the solid ground plane not having a cutout portion, causing the operation of the another circuit to become unstable. Therefore, a slit (ground plane cutout portion) is inevitably provided in the ground plane. However, such a slit causes the flow of the return current generated due to the high-frequency signal to flow across, or in other words, traversing, the slit. As a result, a problem occurs in that the characteristic impedance of the high-frequency signal increases, and the EMC deteriorates.

In other words, the problem of isolating the DC potential between different ground planes by a slit, and the problem of blocking the return current caused by a high-frequency signal wired across (traversing) the slit are in a trade-off relationship, and achieving both is difficult with the current technique.

Note that, although it is conceivable to significantly change the wiring pattern from a conventional wiring pattern in order to solve the above problem, this would increase the burden on the designer and also lead to issues such as increased costs.

Patent Document 1 described above does not describe such problems, and also does not mention any means for solving the problems.

An object of the present invention is, in a wiring board having a high frequency transmission path, in a case where a ground plane is DC-isolated by a slit portion to provide two ground surfaces, to reduce a rise or disturbance in impedance caused by reflections and the like of a return current flowing in the ground plane due to an AC signal flowing through the high-frequency transmission path, without being accompanied by significant changes to the wiring pattern.

Other objects of the present invention will become apparent to those skilled in the art by referring to the aspects and best modes exemplified below, as well as the accompanying drawings.

### Solution to Problem

Hereinafter, in order to easily understand the outline of the present invention, aspects according to the present invention will be exemplified.

In a first aspect, a wiring board includes: a wiring layer provided on a first surface of an insulating substrate having a predetermined thickness, and a flat shape; and a ground plane provided on a second surface that opposes the first surface via the insulating substrate; wherein the wiring layer includes a signal transmission pattern serving as a transmission path that transmits a high-frequency signal, a first ground pattern serving as a first ground surface that defines a reference potential in the wiring board, and a second ground pattern serving as a second ground surface that is DC-isolated from the first ground pattern, and which functions as an AC ground for an AC signal flowing through the signal transmission pattern, the second ground pattern including a ground pattern for an electronic component, the ground pattern for an electronic component being connected to another pole of an electronic component that is mounted as a result of one pole being connected to the signal transmission pattern, the ground plane is formed with a first cutout portion, being a cutout portion for the electronic component, which is formed at a position facing the electronic component mounted on the wiring layer via the insulating substrate, and in which a conductor layer constituting the second ground pattern is removed, and a second cutout portion serving as a slit portion that electrically isolates a first ground plane corresponding to the first ground pattern of the wiring layer and a second ground plane corresponding to the second ground pattern of the wiring layer, in a transparent plan view as viewed from the first surface side of the insulating substrate, the first and second cutout portions are arranged such that at least a portion is overlapping, in a transparent plan view as viewed from the first surface side of the insulating substrate, the ground pattern for an electronic component included in the second ground pattern extends in a transmission direction of the AC signal across the second cutout portion serving as the slit portion, the first ground plane is electrically connected to the ground pattern for an electronic component by a first through-conductor that penetrates through the insulating substrate, the second ground plane is electrically connected to the ground pattern for an electronic component by a second through-conductor that penetrates through the insulating substrate, and the first through-conductor, the ground pattern for an electronic component, and the second through-conductor constitute a bypass path that causes a return current, which is generated in the ground pattern in response to the AC signal flowing in the signal transmission path, to flow around the second cutout portion serving as the slit portion.

In the first aspect, a bypass path having a bridge structure that causes the return current to efficiently flow is easily constructed by effectively utilizing the existing ground wiring pattern.

Even if the path of the return current is blocked by the slit portion of the ground plane, the return current can efficiently flow via the bypass path formed by the bridge structure mentioned above through a shortest and straight path with few disturbances.

Therefore, reflections and waveform distortion in the return current are sufficiently suppressed. Accordingly, an increase in the characteristic impedance of the high-frequency signal transmission path is suppressed, allowing the signal quality to be ensured within an allowable range. In addition, it becomes possible to suppress a decrease in the EMC of the wiring board (or the circuit board in a case where a mounted component is also included).

The bypass path having the bridge structure described above can be easily realized by arranging (laying out) a first cutout portion formed in the ground pattern directly under an electronic component mounted on the wiring layer (with one pole the electronic component connected to the ground pattern for an electronic component), and a second cutout portion, which serves as a slit portion that is similarly formed in the ground pattern and electrically separates two ground patterns having different DC potentials, such that at least a portion overlaps in a transparent plan view as viewed from the wiring pattern side of the upper layer.

This point will be described below.

The first cutout portion formed in the ground plane directly under the electronic component is formed to suppress the high-speed transmission of high-frequency signals from being hindered by a parasitic capacitance, which occurs when a large parasitic capacitance is generated between the electronic component and the ground plane directly under the electronic component.

In other words, because the electronic component has a large mounting area, a large parasitic capacitance is formed between the bottom surface of the electronic component and the ground plane area directly under the electronic component, and since the electronic component functions as a capacitive component, the waveform of the high-frequency signal becomes less sharp, and hinders the high-speed transmission of the high-frequency signal.

In order to prevent this, the first cutout portion is provided in the ground plane directly under the electronic component, and by removing a conductor layer of the ground, the formation of the parasitic capacitance described above is prevented, which suppresses a decrease in the transmission speed and distortion in the waveform of the high-frequency signal.

In the present aspect, the first cutout portion is positioned so as to overlap the slit portion, which is the second cutout portion.

The first cutout portion is, as described above, located directly under the electronic component. Viewed differently, this means that an electronic component is always directly above the first cutout portion.

Further, the electronic component is provided between the signal line extending across the slit portion, and the ground pattern for an electronic component. Therefore, the ground pattern for an electronic component is always present in the vicinity of the electronic component.

In addition, because the electronic component is connected to the high-frequency signal transmission path, rapid potential fluctuations constantly occur at one pole of the electronic component, and the ground pattern for an electronic component needs to absorb the potential fluctuations to stabilize the ground potential. Therefore, the ground pattern for an electronic component has a relatively larger area compared to normal wiring.

Having a large area means, in other words, that the ground pattern for an electronic component extends in the signal transmission direction across (traversing) the slit portion serving as the second cutout portion formed in the ground plane directly below.

Therefore, when the first cutout portion is positioned so as to overlap with the second cutout portion, a layout state of the wiring and ground plane is automatically realized where there is always the electronic component directly above, and in the vicinity of the electronic component, there is always the ground pattern for an electronic component having a large area extending across the slit portion (this can be referred to as automatic positioning of the wiring pattern and the like by a kind of self-alignment).

Further, one ground pattern that is isolated by the slit portion is connected through the shortest path, via a first through-conductor (such as a through-via), to a position of the ground pattern for an electronic component of the upper layer that is further toward the front side than the slit portion, and the other ground plane that is isolated by the slit portion is connected through the shortest path, via second through-conductors (such as through-vias), to a position of the ground pattern for an electronic component of the upper layer that is further toward the rear side than the slit portion.

As a result, it is possible to construct a bridge-like bypass path using the first through-conductor, the ground pattern for an electronic component, and the second through-conductors that allows the return current to efficiently flow by bypassing the second cutout portion serving as the slit portion.

In the present aspect, because the existing ground pattern for an electronic component is effectively utilized, there is no need to add a new ground pattern for an electronic component.

Moreover, by changing the layout such that the first and second cutout portions overlap, the ground pattern for an electronic component can be automatically positioned (by a self-aligning positioning) across (traversing) the slit portion, and the bypass path of the return current can be easily realized with only minor layout changes as necessary (for example, slight changes to the shape of the ground pattern for an electronic component, or a minor layout change such as adding a small number of through-conductors (such as through-vias)), without significantly changing the wiring pattern.

Therefore, the burden on the designer is reduced, and cost increases can be suppressed.

In a second aspect dependent on the first aspect, the electronic component may be a high-value resistor having one pole connected to the signal transmission pattern, and another pole connected to the ground pattern for an electronic component, and that DC-isolates the first and second ground patterns, or a diode that has one pole connected to the signal transmission pattern, and another pole connected to the ground pattern for an electronic component, and that is used to suppress an overcurrent or an overvoltage in the signal transmission pattern.

In the second aspect, the electronic component may be a high-value resistor connected to the high-frequency signal transmission pattern to DC-isolate the two ground planes, or a diode constituting an overcurrent (overvoltage) protection circuit or the like.

Such electronic components are not specialized components, and are commonly used in high-frequency circuits. Further, in the vicinity of such electronic components, a ground pattern for an electronic component with a large area is always laid out in order to stabilize the ground potential.

In the present aspect, by utilizing the existing ground pattern for an electronic component, which is present in such a normal high-frequency circuit, as a conductor that is a component of the bypass path of the return current, it is possible to effectively suppress an increase in the characteristic impedance of the high-frequency transmission path and a decrease in signal quality without requiring special changes to the wiring pattern and the like.

In a third aspect dependent on the first or second aspect, the AC signal may be a differential current signal.

In the present aspect, the AC signal (high-frequency signal) is transmitted as a differential current signal. Differential current transmission is a transmission method that uses two signal lines, causes currents of opposite phases to each other to flow, and transmits using the potential difference between the signal lines.

According to such a transmission method, even if the same noise is applied to each signal line, the noise is canceled out because differential current transmission looks at the potential difference between the signal lines. Therefore, circuit malfunctions and the like can be suppressed. In addition, an effect of improving electromagnetic interference (EMI) can also be expected.

In a fourth aspect dependent on any one of the first to third aspects, in a transparent plan view as viewed from a first surface side of the insulating substrate, the first cutout portion, which is a cutout portion for an electronic component, may overlap the second cutout portion and, among ground patterns isolated by the slit portion, a ground pattern on a receiving end side of the high-frequency signal, or the first cutout portion, which is the cutout portion for an electronic component, may overlap the second cutout portion and, among ground patterns isolated by the slit portion, a ground pattern on a transmitting end side of the high frequency signal, or the first cutout portion, which is the cutout portion for an electronic component, may overlap both the second cutout portion and two ground patterns isolated by the slit portion.

The fourth aspect describes examples of acceptable overlapping layouts of the first and second cutout portions. In the present aspect, three examples of overlapping layouts are described. However, any of these layouts may be used, because the isolation of the ground patterns by the slit portion is achieved by any layout.

In other words, when aligning the first and second cutout portions, even if a slight deviation occurs due to an alignment error, because any of the layouts described above is acceptable, the alignment to obtain an overlap is simplified, and the burden of layout design can be reduced.

In a fifth aspect dependent on any one of the first to fourth aspects, in a transparent plan view as viewed from a first surface side of the insulating substrate, the first and second ground patterns may oppose each other in parallel via the second cutout portion serving as the slit portion, or in a transparent plan view as viewed from a first surface side of the insulating substrate, the first and second ground patterns may oppose each other and each may have a corner portion at a position corresponding to the other via the second cutout portion serving as the slit portion.

In the present aspect, the first and second ground patterns isolated by the second cutout portion serving as the slit portion may be arranged to oppose each other in parallel via the second cutout portion (when the thickness of each ground pattern is also considered, arranged with parallel opposing surfaces).

In this case, local electric field concentration does not occur in each ground pattern, and ground patterns with a more stable ground potential can be obtained.

Furthermore, the first and second ground patterns may be arranged to oppose each other and each may have a corner portion at a corresponding position via the second cutout portion serving as the slit portion (when the thickness of each ground pattern is also considered, arranged with parallel opposing surfaces).

In this case, a slight local electric field concentration occurs at the opposing corner portion of each ground pattern, and it can be expected that the return current will flow across the second cutout portion serving as the slit portion via such a section. Further, in this case, in addition to the bridge-like bypass path described above, a current path that flows over the second cutout portion described above is also formed, which contributes to suppressing the increase in the impedance of the return current, and suppressing reflections and waveform distortion, and the like.

In a sixth aspect dependent on any one of the first to fifth aspects, the wiring board may be a multilayer wiring board formed by laminating a plurality of the insulating substrates having the wiring layer and the ground plane.

In the sixth aspect, a multilayer wiring board is used as the wiring board. In a wiring board (a circuit board on which an electronic component is mounted), as the number of layers increases, the wiring patterns and the like become more complicated, making it difficult to keep the EMC within an allowable range.

As a result of applying the present invention, it becomes easier to keep the EMC within an allowable range even in a multilayer board with a large number of layers, and the burden of designing the wiring board is reduced.

In a seventh aspect dependent on any one of the first to fifth aspects, the wiring board may be a vehicle wiring board that is mounted in a vehicle, and may supply the AC signal to an in-vehicle display device mounted in the vehicle via the signal transmission pattern.

In the seventh aspect, a vehicle wiring board that is mounted in a vehicle is used as the wiring board. A vehicle wiring board is strictly required to have noise resistance, or characteristics that reduce noise emission. As a result of applying the present invention, it becomes easier to keep the EMC within an allowable range, the quality of the wiring board (circuit board) is improved, and the burden of designing the wiring board (circuit board) and the like can be reduced.

In an eighth aspect, a vehicle display device includes the wiring board according to any one of the first to fifth aspects, which is mounted in a vehicle; a vehicle display device mounted in the vehicle; and a vehicle display control device that is mounted in the vehicle, and supplies to the wiring board an AC signal that is needed for display on the vehicle display device.

As a result of applying the present invention to a vehicle display device, a decrease in the display quality of the vehicle display (including an instrument display, a traffic guidance display, and the like) is suppressed. For example, an accurate and easily viewed vehicle display can be realized.

In a ninth aspect dependent on the eighth aspect, the vehicle display device may be an instrument display device that displays information indicating a state of the vehicle.

An instrument display shows important information such as the vehicle speed and engine speed, and is required to present accurate and easily viewed information. As a result of applying the present invention, a decrease in the quality of the instrument display is suppressed, and an accurate and easily viewed instrument display can be realized.

Those skilled in the art will readily understand that the exemplified aspects according to the present invention may be further modified without departing from the spirit of the present invention.

### BRIEF DESCRIPTION OF DRAWINGS

FIGS. 1A to 1D are diagrams showing a problem before applying the present invention, and FIG. 1E is a diagram showing the reason why the problem is solved by applying the present invention.

FIG. 2A is a diagram showing an example of a transmission path of a differential current signal in a four-layer wiring board, FIG. 2B is a diagram showing an example of a path of a return current before applying the present invention, and FIG. 2C is a diagram showing an example of a path of a return current after applying the present invention.

FIG. 3 is a diagram showing an example of a circuit mounted on a circuit board, in which an electronic component is mounted on a wiring board.

FIG. 4 is a diagram showing an example of layout patterns for each of first to fourth layers (L1 to L4) when the circuit of FIG. 3 is mounted on a four-layer multilayer board to which the present invention is applied.

FIGS. 5A to 5E are diagrams showing an example of an overlap mode between a first cutout portion for an electronic component and a second cutout portion serving as a slit portion, and an example of a layout shape of a ground pattern in each of the first and second cutout portions.

### DESCRIPTION OF EMBODIMENTS

The best modes for carrying out the invention described below are used to more easily understand the present invention. Therefore, those skilled in the art should note that the present invention is not unreasonably limited by the embodiments described below.

### First Embodiment

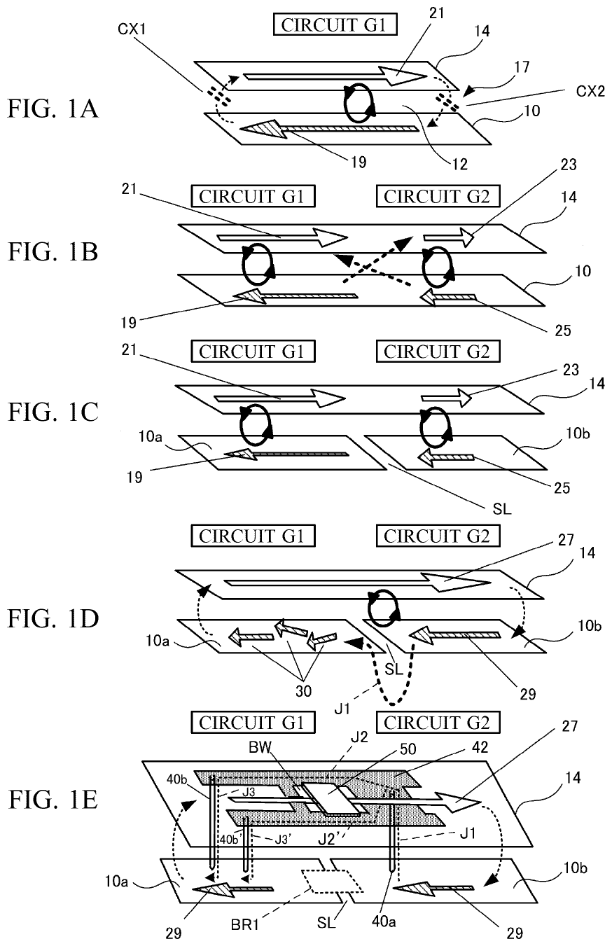

The description will now refer to FIGS. 1A to 1E. FIGS. 1A to 1D are diagrams showing a problem before applying the present invention, and FIG. 1E is a diagram showing the reason why the problem is solved by applying the present invention.

The wiring board shown in FIG. 1A includes a wiring layer 14 provided on a first surface, being an upper layer, of an insulating substrate 17 having a predetermined thickness and a flat shape (in the case of a rigid board, for example, an insulating substrate made of glass epoxy), and a ground plane 10 provided on a second surface, being a surface layer opposite the first surface, being the upper layer, via the insulating substrate 17.

Although not illustrated in FIG. 1A, the wiring layer 14 includes a signal transmission pattern as a transmission path through which a high-frequency signal is transmitted.

In FIG. 1A, when a high-frequency signal (microwave) indicated by an arrow 21 flows from a left end portion (transmitting end portion) to a right end portion (receiving end portion) in the diagram, an eddy current is generated in the signal pattern, and electromagnetic coupling occurs with the ground plane 10 of the lower layer due to the eddy current. In the diagram, a shape combining an ellipse and arrows is shown, and this indicates that electromagnetic coupling is occurring between the wiring layer 14 of the upper layer and the ground pattern 10 of the lower layer.

As a result of the electromagnetic coupling, a return current (a reflected wave in a case where the high-frequency signal is recognized as a transmitted microwave) 19 is generated in a direction opposite to the direction in which the high-frequency signal flows, directly under the transmission path of the high-frequency signal in the ground plane 10 of the lower layer.

Note that, in the drawing, the reference signs CX1 and CX2 represent parasitic capacitances formed between the wiring layer 14 and the ground plane 10. Furthermore, an electronic circuit constructed by mounting an electronic component on the wiring layer of the wiring board has the characteristics of a distributed constant circuit.

Moreover, the circuit board itself has the function of a microstrip line (a microwave transmission path having a structure in which a coaxial cable is cut into two slices, and one half is extended in a planar shape) that transmits microwaves.

In FIG. 1B, two different circuits G1 and G2 are mounted on the wiring layer 14, and for this reason, the return current 19 corresponding to the circuit G1 and a return current 25 corresponding to the circuit G2 flow in the ground plane 10 in the lower layer.

In FIG. 1B, the ground plane 10 is a continuous (solid) ground pattern used in common for the circuits G1 and G2.

Therefore, the problem of crosstalk occurs when the circuits G1 and G2 operate independently, in which the operation of one circuit causes a fluctuation in the potential of the ground plane 10 at the position corresponding to the one circuit, and the fluctuation propagates to the other circuit via the solid ground plane 10, causing the operation of the other circuit to become unstable. In FIG. 1B, two dashed arrows are shown, and this indicates that crosstalk is occurring.

In FIG. 1C, in order to prevent crosstalk, a slit portion SL (cutout portion in the conductor layer) is provided in the ground plane 10. As a result, the ground plane 10 is isolated into two ground planes 10a and 10b corresponding to each of the circuits G1 and G2. As a result of providing the slit portion SL, the return current corresponding to one circuit is prevented from flowing into the region of the ground plane corresponding to the other circuit, which prevents crosstalk from occurring.

In FIG. 1D, in the structure where the ground plane 10 is isolated into two ground planes 10a and 10b by the slit portion SL, a high-frequency signal (microwave) indicated by an arrow 27 flows in the wiring layer 14 of the upper layer from the left end portion (transmitting end portion) to the right end portion (receiving end portion) in the diagram.

In this case, the return current 29 first flows through the ground plane 10b, but is then blocked by the slit portion (cutout portion) SL.

For this reason, the return current 29 flows by making a large detour through an unordered current path J1 where current can flow, and here, large reflections and waveform distortions occur. In FIG. 1D, such a disturbance of the return current is represented by arrows 30 with inconsistent directions.

The disturbance of the return current causes a problem where the characteristic impedance of the high-frequency signal 27 in the wiring layer 14 rises, and the signal quality decreases.

As a countermeasure to this, in FIG. 1E, a bypass path with a bridge structure that causes the return current to efficiently flow is easily constructed by effectively utilizing the existing ground wiring pattern. According to the structure of FIG. 1E, even if the path of the return current is blocked by the slit portion SL, the return current can efficiently flow via the bypass path formed by the bridge structure mentioned above through a shortest and straight path with little disturbance. This point will be described below.

In FIG. 1E, the ground pattern of the lower layer is isolated into two ground patterns (ground pattern regions) 10a and 10b by the slit portion SL in the same manner as FIGS. 1C and 1D.

A point to be noted here is that a layout is adopted in which, in a transparent plan view as viewed from the wiring layer 14 side of the upper layer (in other words, viewed from the upper side), a cutout portion BR corresponding to an electronic component 50 is superimposed on the slit portion SL.

In the following description, the cutout portion BR corresponding to the electronic component 50 may be referred to as a “first cutout portion”, and the slit portion SL may be referred to as a “second cutout portion”.

The first cutout portion BR1 formed in the ground plane directly under the electronic component 50 is formed to suppress the high-speed transmission of high-frequency signals from being hindered by a parasitic capacitance, which occurs when a large parasitic capacitance is generated between the electronic component 50 and the ground plane directly under the electronic component.

In other words, because the electronic component 50 has a large mounting area compared to a normal wiring pattern, a large parasitic capacitance is formed between the bottom surface of the electronic component 50 and the ground plane area directly under the electronic component, and since the electronic component 50 functions as a capacitive component, the waveform of the high-frequency signal becomes less sharp, and hinders the high-speed transmission of the high-frequency signal.

In order to prevent this, the first cutout portion is provided in the ground plane directly under the electronic component 50, and by removing the ground conductor layer, the formation of the parasitic capacitance described above is prevented, which suppresses a decrease in the transmission speed and distortion in the waveform of the high-frequency signal.

Before application of the present invention, there were no rules dictating the layout in terms of the relative positional relationship between the first and second cutout portions, and each cutout portion could be freely arranged.

In contrast, in the present invention, a layout rule is adopted in which the first cutout portion BR1 is positioned so as to overlap the slit portion SL, which is the second cutout portion.

The first cutout portion BR1 is, as described above, located directly under the electronic component 50. Viewed differently, this means that the electronic component 50 is always directly above the first cutout portion BR1.

Further, the electronic component 50 is provided between the signal line extending across the slit portion SL, and the ground pattern for an electronic component. Therefore, the ground pattern for an electronic component (reference sign 42 in FIG. 1E) is always present in the vicinity of the electronic component 50.

Note that a cutout portion BW where no conductor is formed is provided in the region of the ground pattern 42 for an electronic component on which the electronic component 50 is mounted.

In addition, because the electronic component 50 is connected to the high-frequency signal transmission path, rapid potential fluctuations constantly occur at one pole of the electronic component 50, and the ground pattern 42 for an electronic component needs to absorb the potential fluctuations to stabilize the ground potential. Therefore, the ground pattern 42 for an electronic component has a relatively larger area compared to normal wiring.

Having a large area means, in other words, as shown in FIG. 1E, that the ground pattern 42 for an electronic component extends in the signal transmission direction across (traversing) the slit portion SL serving as the second cutout portion formed in the ground plane directly below.

Therefore, when the first cutout portion BR1 is positioned so as to overlap with the second cutout portion SL, a layout state of the wiring and ground plane is automatically realized where there is always the electronic component 50 directly above, and in the vicinity of the electronic component 50, there is always the ground pattern 42 for an electronic component having a large area extending across the slit portion SL (this can be referred to as automatic positioning of the wiring pattern and the like by a kind of self-alignment).

Further, as shown in FIG. 1E, one ground pattern 10b that is isolated by the slit portion SL is connected through the shortest path, via a first through-conductor (such as a through-via) 40a, to a position of the ground pattern 42 for an electronic component of the upper layer that is further toward the front side than the slit portion SL (the side that is closer to the receiving end of the signal transmission path), and the other ground plane that is isolated by the slit portion SL is connected through the shortest path, via second through-conductors (such as through-vias) 40b and 40b′, to a position of the ground pattern 42 for an electronic component of the upper layer that is further toward the rear side than the slit portion (the side that is closer to the transmission end of the signal transmission path).

As a result, it is possible to construct a bridge-like bypass path using the first through-conductor 40a, the ground pattern 42 for an electronic component, and the second through-conductors 40b and 40b′ that allows the return current to efficiently flow by bypassing the second cutout portion SL serving as the slit portion.

In FIG. 1E, the flow of the return current flowing via the bypass path is indicated by dashed arrows, and each portion is labeled with reference signs J1, J2, J2′, J3, and J3′.

This allows the return current 29 flowing in the ground plane 10b to efficiently flow to the ground plane 10a with almost no waveform distortion.

In FIG. 1E, because the existing ground pattern for an electronic component is effectively utilized, there is no need to add a new ground pattern for an electronic component.

Moreover, by changing the layout such that the first and second cutout portions BR and SL overlap, the ground pattern 42 for an electronic component can be automatically positioned (by a self-aligning positioning) across (traversing) the slit portion SL, and the bypass path of the return current can be easily realized with only minor layout changes as necessary (for example, slight changes to the shape of the ground pattern 42 for an electronic component, or a minor layout change such as adding a small number of through-conductors (such as through-vias: reference signs 40a, 40b, and 40b′ in FIG. 1E), without significantly changing the wiring pattern. Therefore, the burden on the designer is reduced, and cost increases can be suppressed.

### Second Embodiment

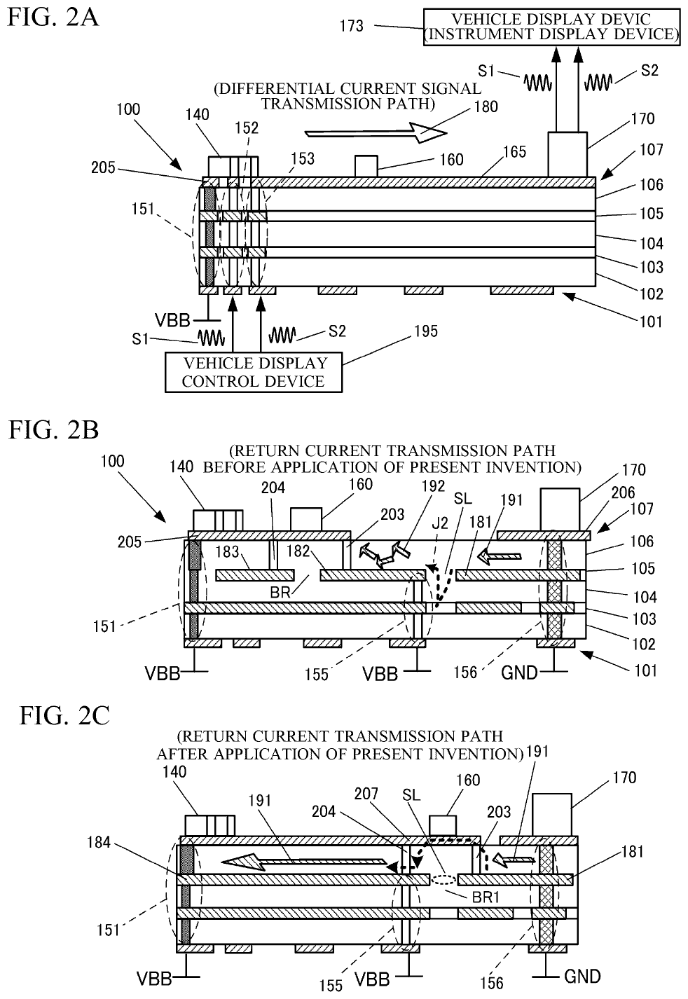

The description will now refer to FIGS. 2A to 2C. FIG. 2A is a diagram showing an example of a transmission path of a differential current signal in a four-layer wiring board, FIG. 2B is a diagram showing an example of a path of a return current before applying the present invention, and FIG. 2C is a diagram showing an example of a path of a return current after applying the present invention.

FIG. 2A shows an example of the structure of a transmission path of a differential current signal in a four-layer wiring board (referred to as a “four-layer circuit board” when mounted electronic components are considered: the term “four-layer wiring board” will be used in the following description).

A four-layer wiring board 100 includes a wiring layer 101 of a first layer, ground planes 103 and 105 of each of a second and third layer, a wiring layer 107 of a fourth layer, and electrically insulating substrates (here, assumed to be a glass epoxy resin) 102, 104, and 106.

The four-layer wiring board 100 in FIG. 2A is a multilayer wiring board for vehicle (in-vehicle) use that is mounted in a vehicle.

The four-layer wiring board 100 has a function of transmitting a pair of differential current signals S1 and S2 output from a vehicle display control device 195 to a connector 170 for connection to a vehicle display device (here, assumed to be an instrument display device that displays vehicle information such as the vehicle speed) 173, via a high-frequency signal transmission path 165 included in the wiring layer 107 of the fourth layer, which is the uppermost layer.

The differential current signals S1 and S2 output from the connector 170 are supplied to the vehicle display device 173, and the vehicle display device 173 displays instrument information (information such as the vehicle speed) indicating a vehicle state.

An IC (Integrated Circuit) 140 having a transmitting function (and a receiving function) of a high-frequency signal 180, and an electronic component 160 such as a capacitor or diode, is connected to the high-frequency signal transmission path 165 included in the wiring layer 107 of the fourth layer.

In the diagram, reference sign 151 represents a through-conductor structure for a VBB, which is connected to an AC ground electrode 205 of the IC 140 and is configured by a plurality of through-conductors (through-vias) for supplying an AC ground VBB to the IC 140. Reference signs 152 and 153 represent through-conductor structures for S1 and S2, which are constituted by a plurality of through-conductors (through-vias) for supplying the differential current signals S1 and S2 to the IC 140.

FIG. 2B shows an example of the structure of a return current path in a four-layer wiring board before applying the present invention. In FIG. 2B, the same parts as in FIG. 2A are denoted by the same reference signs.

In FIG. 2(B), the wiring layer 107 of the fourth layer, which is the uppermost layer, includes a wiring region 205 for an AC ground VBB, which is at the potential of the AC ground VBB, and a wiring region 206 for a DC ground GND, which is at the potential of the DC ground GND.

The ground plane 105 of the third layer is provided with three ground plane regions 181, 182, and 183.

The ground plane region 182 of the third layer and wiring region 205 of the fourth layer are electrically connected via a through-conductor (through-via) 203. The wiring region 205 of the fourth layer and the ground plane region 183 of the third layer are electrically connected via a through-conductor (through-via) 204.

Furthermore, in the diagram, reference sign 155 represents a through-conductor structure for the AC ground VBB, which is connected to the ground plane region 182 and constituted by a plurality of through conductors (through-vias).

Reference sign 156 represents a through-conductor structure for the DC ground GND, which is connected to a DC ground electrode 206 of the connector 170, supplies a DC ground GND to the connector 170, and is constituted by a plurality of through-conductors (through-vias).

As previously described, the ground plane region 181 for the DC ground GND and the ground plane region 182 for the AC ground VBB are isolated by a slit portion (second cutout portion) SL.

In addition, a cutout portion (first cutout portion) BR for an electronic component is provided in the ground plane 105 located directly under (below) the electronic component 160.

As previously described with reference to FIG. 1D, the presence of the slit portion SL prevents a return current 191 from flowing via the shortest path. In this case, the return current flows via a large bypass path J2, which causes large reflections and waveform distortions. In FIG. 2B, this disturbance of the return current is indicated by a plurality of arrows 192 pointing in different directions.

FIG. 2C shows an example of the structure of a return current path in a four-layer wiring board after applying the present invention. In FIG. 2C, the same parts as in FIG. 2B are denoted by the same reference signs.

In FIG. 2C, the wiring layout has been slightly changed. As previously described with reference to FIG. 1E, in a transparent plan view as viewed from above (the wiring side of the fourth layer), at least a portion of the cutout portion for an electronic component (first cutout portion) BR overlaps the slit portion (second cutout portion) SL.

As described above, when the first cutout portion BR1 is positioned so as to overlap the second cutout portion SL, a layout state of the wiring and ground plane is automatically realized where there is always the electronic component 160 directly above, and in the vicinity of the electronic component 160, there is always the ground pattern 207 for an electronic component having a large area extending across the slit portion SL when viewed in a transparent plan view (this can be referred to as automatic positioning of the wiring pattern and the like by a kind of self-alignment).

Further, the ground pattern region 181 on the receiving end side of the high-frequency signal (referred to as the front side) that is isolated by the slit portion SL is connected through the shortest path, via a through-conductor (such as a through-via) 203, to a position on the ground pattern 207 for an electronic component of the upper layer further toward the front side than the slit portion SL. Also, the other ground pattern region 184 that is isolated by the slit portion SL is connected through the shortest path, via a through-conductor (such as a through-via) 204, to a position on the ground pattern 207 for an electronic component of the upper layer further toward the transmitting end side of the high-frequency signal (referred to as the rear side) than the slit portion SL when viewed in a transparent plan view.

As a result, it is possible to easily construct a bridge-like bypass path using the through-conductor 203, the ground pattern 207 for an electronic component, and the through-conductor 204 that allows the return current to efficiently flow by bypassing the second cutout portion SL serving as the slit portion. In FIG. 2C, the flow of the return current flowing via the bypass path is indicated by a dashed arrow.

In the four-layered wiring board of FIG. 2C, because the existing ground pattern 207 for an electronic component is effectively utilized, there is no need to add a new ground pattern for an electronic component.

Moreover, by changing the layout such that the first and second cutout portions BR and SL overlap, the ground pattern 207 for an electronic component can be automatically positioned (by a self-aligning positioning) across (traversing) the slit portion SL when viewed in a transparent plan view, and the bypass path of the return current can be easily realized with only minor layout changes as necessary (for example, slight changes to the shape of the ground pattern 207 for an electronic component, or a minor layout change such as adding a small number of through-conductors (such as through-vias)), without significantly changing the wiring pattern. Therefore, the burden on the designer is reduced, and cost increases can be suppressed.

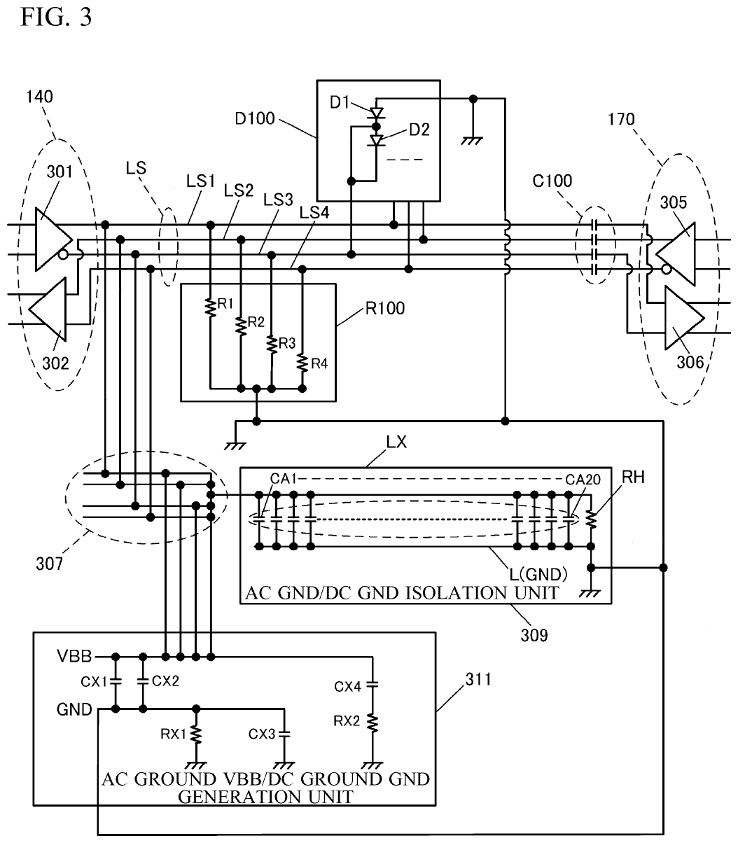

The description will now refer to FIG. 3. FIG. 3 is a diagram showing an example of a circuit mounted on a circuit board, in which an electronic component is mounted on a wiring board. In FIG. 3, the same components as those in the drawings described above are denoted by the same reference signs.

In FIG. 3, four transmission lines LS1 to LS4 (collectively referred to as LS in the diagram) are provided as transmission paths that transmit a high-frequency signal of a differential current signal.

An IC 140 (having a transmitting unit 301 and a receiving unit 302) serving as a high-frequency signal communication device is connected to one end of the transmission lines LS1 to LS4, and a connector 170 (having a transmitting unit 305 and a receiving unit 306) is connected to the other end.

Note that a DC-blocking capacitor C100 is interposed in the transmission lines (transmission paths) LS1 to LS4 to allow the DC potentials at the one end side and the other end side to be different.

Also, in the diagram, reference sign D100 represents a diode unit that is provided where overcurrent (overvoltage) protection diodes D1, D2, and the like, are provided.

Reference sign R100 represents a resistor unit (including high-value resistors R1 to R4) for keeping the impedance between the AC ground VBB and the DC ground GND high.

Furthermore, reference sign 307 represents a relay unit that relays between the AC ground VBB and the DC ground GND. An example of the relay unit 307 is a conductor structure configured by through-conductors (through-vias) provided penetrating a plurality of insulating substrates.

Reference sign 309 represents an AC ground VBB/DC ground GND isolation unit that isolates the AC ground VBB and the DC ground GND. A plurality of bypass capacitors CA1 to CA20 and a high-value resistor RH are connected between the wiring LX and the DC ground GND. As a result, AC noise components superimposed on the wiring LX are released to the DC ground GND via the bypass capacitors CA1 to CA20. Therefore, the wiring LX functions as the AC ground VBB.

Reference sign 311 represents an AC ground VBB/DC ground GND generation unit. Reference signs CX1 to CX4 represent bypass capacitors, and RX2 represents a high-value resistor that suppresses a large current from flowing to the AC ground VBB.

Furthermore, reference sign RX1 indicates a resistor that grounds the DC ground GND, and reference sign CX3 indicates a capacitor for stabilizing the potential of the DC ground (ground potential) by releasing AC noise components superimposed on the DC ground GND to the ground.

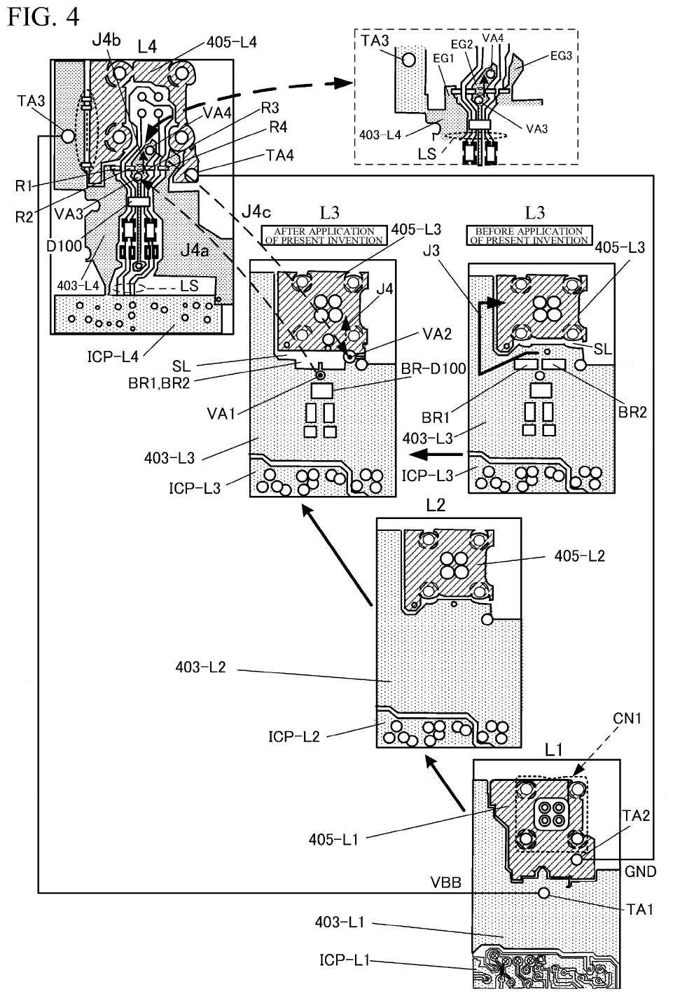

The description will now refer to FIG. 4. FIG. 4 is a diagram showing an example of layout patterns for each of first to fourth layers (L1 to L4) when the circuit of FIG. 3 is mounted on a four-layer multilayer board to which the present invention is applied.

In FIG. 4, the signs L1 to L4 represent the first to fourth layers. In FIG. 4, the first layer (L1) is shown at the bottom, and the depicted position moves upward as the layer becomes higher, through the second layer, third layer, and fourth layer.

An AC ground (VBB) pattern and a DC ground (GND) pattern are provided on each of the first to fourth layers (L1 to L4), and the same type of patterns on each layer are connected by through-conductors (through-vias) of each layer and held at the same potential, as previously shown in FIG. 2.

First, the wiring pattern of the wiring layer of the first layer (L1) will be described. As shown in the diagram, in the first layer (L1), a wiring pattern for the IC 140 (including a pattern for high-frequency signals and a pattern for the AC ground (VBB)) ICP-L1, an AC ground (VBB) pattern 403-L1, and a DC ground (GND) pattern 405-L1 are provided. A region indicated by reference sign CN1 in the diagram (a substantially square region indicated by a dashed line) is a region corresponding to the mounting area of the connector 170. Terminal regions TA1 and TA2 corresponding to through-conductors (through-vias) are provided in the wiring pattern of the first layer.

The through-conductors inserted through the terminal regions TA1 and TA2 of the first layer (L1) (held at the VBB and GND potentials: not shown) are connected to the through-conductors (through-vias: not shown) of the terminal regions TA3, TA4 of the fourth layer (L4).

The wiring pattern of the wiring layer of the second layer (L2) is provided with a ground plane pattern ICP-L2 for the IC 140, an AC ground (VBB) pattern 403-L2, and a DC ground (GND) pattern 405-L2.

For the third layer (L3), both the ground plane pattern before the application of the present invention (left side) and the ground plane pattern after the application of the present invention (right side) are shown for ease of understanding.

In the third layer (L3), similarly to the second layer, a ground plane pattern ICP-L3 for the IC 140, an AC ground (VBB) pattern 403-L3, and a DC ground (GND) pattern 405-L3 are provided. Furthermore, cutout portions (first cutout portions) BR1 and BR2 for an electronic component (here, assumed to be the resistor unit R100 (high-value resistors R1 to R4) in FIG. 3), and a slit portion (second cutout portion) SL are provided.

In the pattern before the application of the present invention (the pattern shown on the right side of the diagram), as previously described, the cutout portions for an electronic component (first cutout portions) BR1 and BR2 do not have an overlap with the slit portion (second cutout portion) SL in a transparent plan view as viewed from the upper side. Therefore, the return current flows by making a large detour, for example, through an unordered bypass path (indicated by a bold arrow in the diagram) J3, which causes large reflections or large waveform distortions, leading to an increase in the characteristic impedance of the high-frequency signal transmission path and a decrease in the signal quality.

In the pattern before the application of the present invention (the pattern shown on the right side of the diagram), as previously described, the cutout portions for an electronic component (first cutout portions) BR1 and BR2 do not have an overlap with the slit portion (second cutout portion) SL in a transparent plan view as viewed from the upper side. Therefore, the return current flows by making a large detour, for example, through an unordered bypass path (indicated by a bold arrow in the diagram) J3, which causes large reflections or large waveform distortions, leading to an increase in the characteristic impedance of the high-frequency signal transmission path and a decrease in the signal quality.

In the pattern after the application of the present invention (the pattern shown on the left side of the diagram), as previously described, the cutout portions for an electronic component (first cutout portions) BR1 and BR2 are disposed so as to overlap with the slit portion (second cutout portion) SL in a transparent plan view as viewed from the upper side.

Furthermore, in the ground plane of the third layer, a cutout portion (first cutout portion) BR-D100 corresponding to the diode unit D100 in which the overcurrent (overvoltage) protection diodes D1, D2, and the like are provided, a cutout portion (first cutout portion) BR-R100 corresponding to the resistor unit R100, and the like are provided.

In the third layer (L3), the slit portion (second cutout portion) SL is substantially formed when the first and second cutout portions BR1 and BR2 are also included, and the isolation of the potential between the AC ground VBB and the DC ground GND is realized.

However, when viewed in a transparent plan view, in the slit portion SL (at the location where the second cutout portion overlaps), it appears as if no slit portion is provided. The pattern of the third layer is provided with through-conductors (through-vias) VA1 and VA2.

In the wiring pattern of the fourth layer (L4), similarly to the second and third layers, a ground pattern ICP-L4 for the IC 140, an AC ground (VBB) pattern 403-L4, and a DC ground (GND) pattern 405-L4 are provided.

Furthermore, cutout portions (first cutout portions) BR1 and BR2 for an electronic component (here, assumed to be the resistor unit R100 (high-value resistors R1 to R4) in FIG. 3), and a slit portion (second cutout portion) SL are provided.

The fourth layer (L4) is provided with high-frequency signal transmission lines (transmission paths) LS (LS1 to LS4 in FIG. 3: represented by a bent solid line in FIG. 4) and AC ground patterns for an electronic component (AC ground pattern regions) connected to one pole of the electronic components (here, high-value resistors R1 to R4).

Inside the dashed rectangle shown in the upper center of FIG. 4, a portion of the pattern including the AC ground pattern for an electronic component (AC ground pattern region) is shown in an enlarged view. The AC ground pattern for an electronic component (AC ground pattern region) is the region indicated by reference signs EG1 to EG3 in the diagram.

In addition, in the fourth layer (L4), the high-value resistors R1 to R4 and the diode unit D100 (diodes D1, D2, and the like) are mounted.

Also, terminal regions TA3 and TA4 and through-conductors (through-vias) VA3 and VA4 are also provided.

As can be understood from FIGS. 3 and 4, according to the patterns to which the present invention has been applied, a shortest bypass path with a bridge structure that allows the return current to flow efficiently is automatically configured as described above.

The bypass path is, specifically, for example, a current path via the through-conductor (through-via) VA1 of the third layer (L3), the through-conductor (through-via) VA3 of the fourth layer (L4), the AC ground pattern for an electronic component (AC ground pattern region) EG2 of the fourth layer (L4), the through-conductor (through-via) VA4 of the fourth layer (L4), and the through-conductor (through-via) VA2 of the third layer (L3). The return current flows via paths J4a, J4b, and J4c (indicated by dashed arrows in the diagram).

Because the return current flows via the shortest bypass path, the increase in the characteristic impedance of the high-frequency signal transmission path is sufficiently suppressed. Therefore, a decrease of the signal quality of the high-frequency signal can be effectively suppressed.

### Third Embodiment

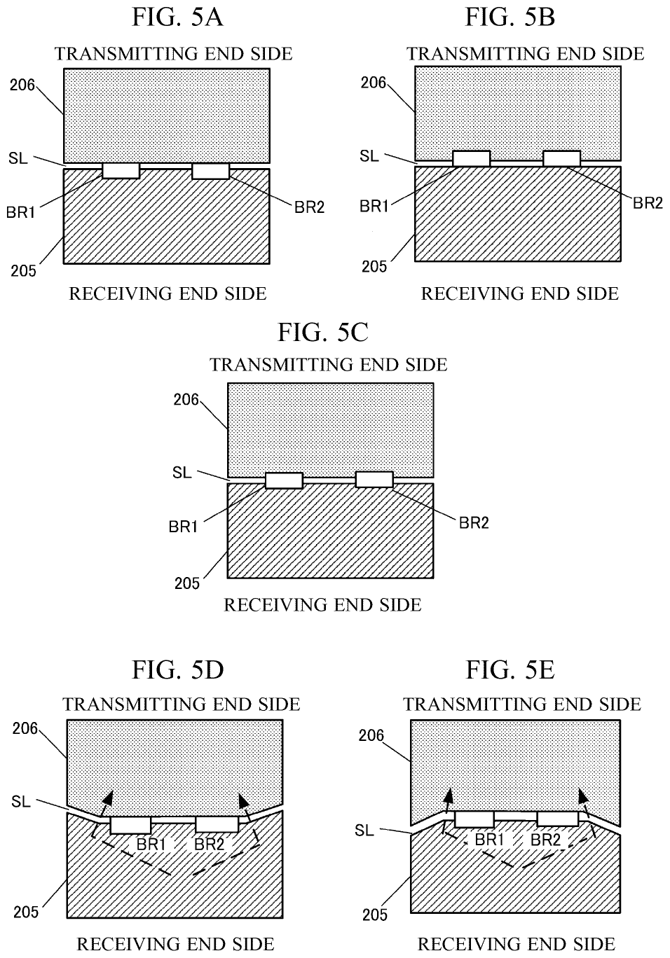

The description will now refer to FIGS. 5A to 5E. FIGS. 5A to 5E are diagrams showing an example of an overlap mode between a first cutout portion for an electronic component and a second cutout portion serving as a slit portion, and an example of a layout shape of a ground pattern in each cutout portion.

FIGS. 5A to 5C show examples of allowable modes of the overlap between the first and second cutout portions BR and SL.

In FIG. 5A, in a transparent plan view as viewed from the first surface side (upper side, or wiring layer side) of the insulating substrate, or in other words, in a transparent plan view as viewed from the wiring layer side (upper side), the first cutout portions BR1 and BR2, which are cutout portions for an electronic component, overlap the second cutout portion SL serving as the slit portion and, among the ground patterns 205 and 206 that are isolated by the slit portion (second cutout portion) SL, the ground pattern 205 on the receiving end side of the high-frequency signal.

In FIG. 5B, the first cutout portions BR1 and BR2, which are cutout portions for an electronic component, overlap the second cutout portion SL serving as the slit portion and, among the ground patterns 205 and 206 that are isolated by the slit portion (second cutout portion) SL, the ground pattern 206 on the transmitting end side of the high-frequency signal.

In FIG. 5C, the first cutout portions BR1 and BR2, which are cutout portions for an electronic component, overlap both the second cutout portion SL serving as the slit portion and the two ground patterns 205 and 206 isolated by the slit portion (second cutout portion).

In FIGS. 5A to 5C, three examples of overlapping layouts are shown, but any of these layouts may be used because the isolation of the ground patterns 205 and 206 by the slit portion SL is achieved by any layout.

In other words, when aligning the first and second cutout portions BR and SL, even if a slight deviation occurs due to an alignment error, because any of the layouts described above is acceptable, the alignment to obtain an overlap is simplified, and the burden of layout design can be reduced.

FIGS. 5D and 5E are diagrams showing an example of the layout shape of a ground pattern in each of the first and second cutout portions.

In FIG. 5D, in a transparent plan view as viewed from the first surface side (upper side, or wiring layer side) of the insulating substrate, the first and second ground patterns 205 and 206 isolated by the slit portion (second cutout portion) SL oppose each other in parallel via the second cutout portion SL serving as the slit portion. When the thickness of each of the ground patterns 205 and 206 is also considered, this can be rephrased as being arranged with parallel opposing surfaces.

In this case, local electric field concentration does not occur in each ground pattern, and ground patterns with a more stable ground potential can be obtained.

In FIG. 5E, in a transparent plan view as viewed from the first surface side (upper side, or wiring layer side) of the insulating substrate, the first and second ground patterns 205 and 206 oppose each other and each has a corner portion at a corresponding position via the second cutout portion SL serving as the slit portion. When the thickness of each of the ground patterns 205 and 206 is also considered, this can be rephrased as being arranged with opposing surfaces having a corner portion.

In this case, a slight local electric field concentration occurs at the opposing corner portion of each ground pattern 205 and 206, and it can be expected that the return current will flow across the second cutout portion serving as the slit portion at such a section.

In FIGS. 5D and 5E, the path of the current flowing in this manner is indicated by dashed arrows.

In the example of FIGS. 5D and 5E, in addition to the bridge-like bypass path described above, a current path that flows over the second cutout portion SL described above is also formed, which contributes to suppressing the increase in the impedance of the return current, and suppressing reflections and waveform distortion, and the like.

### Fourth Embodiment

In the example of FIG. 4 described above, the cutout portions BR1 and BR2 for an electronic component, in which the high-value resistors R1 to R4 serve as electronic components, were overlapped with the slit portion SL serving as the second cutout portion. However, depending on the circuit configuration, the high-value resistors R1 to R4 may not be provided in some cases.

In such cases, for example, the cutout portion BR-D100 for the diode unit D100 may be overlapped with the slit portion SL serving as the second cutout portion. Such modifications and applications can be made as appropriate.

### Experimental Results

The target value for the characteristic impedance of the differential current signal transmission path was 100 ohms, and the design specification, considering variations, has an allowable range of 90 to 110 ohms.

Before applying the present invention, the characteristic impedance was 109.4 ohms. The allowable variation margin was small.

On the other hand, after applying the present invention, the characteristic impedance became 106.5 ohms. The allowable variation margin was expanded, thus simplifying the design.

As described above, according to the embodiments of the present invention, in a wiring board having a high-frequency transmission path, a rise and disturbance of impedance due to reflections and the like of a return current flowing to a ground plane caused by an AC signal flowing through the high-frequency transmission path can be reduced without being accompanied by significant changes to the wiring pattern.

Furthermore, according to an embodiment of the present invention, the first cutout portion for an electronic component such as a high-value resistor connected to the high-frequency signal transmission pattern to DC-isolate the two ground planes, or a diode constituting an overcurrent (overvoltage) protection circuit, can be effectively used.

Such electronic components are not specialized components, and are commonly used in high-frequency circuits. Further, in the vicinity of such electronic components, a ground pattern for an electronic component with a large area is always laid out in order to stabilize the ground potential.

Therefore, by being utilized as a conductor that is a component of the bypass path of the return current in the existing ground pattern for an electronic component, which is present in such a normal high-frequency circuit, it is possible to effectively suppress an increase in the characteristic impedance of the high-frequency transmission path and a decrease in the signal quality without requiring special changes to the wiring pattern and the like.

In addition, in an embodiment of the present invention, a differential current signal can be used as the transmitted AC signal.

Differential current transmission is a transmission method that uses two signal lines, causes currents of opposite phases to each other to flow, and transmits using the potential difference between the signal lines. According to such a transmission method, even if the same noise is applied to each signal line, the noise is canceled out because differential current transmission looks at the potential difference between the signal lines. Therefore, circuit malfunctions and the like can be suppressed. In addition, an effect of improving electromagnetic interference (EMI) can also be expected.

Also, in an embodiment of the present invention, a multilayer wiring board can be used as the wiring board.

In a wiring board (a circuit board on which an electronic component is mounted), as the number of layers increases, the wiring patterns and the like become more complicated, making it difficult to keep the EMC within an allowable range.

As a result of applying the present invention, it becomes easier to keep the EMC within an allowable range even in a multilayer board with a large number of layers, and the burden of designing the wiring board is reduced.

Furthermore, in an embodiment of the present invention, the wiring board may be a vehicle wiring board that is mounted in a vehicle and supplies an AC signal to an in-vehicle display device mounted in the vehicle via a signal transmission pattern (see FIG. 2A).

A vehicle wiring board is strictly required to have noise resistance, or characteristics that reduce noise emission. As a result of applying the present invention, it becomes easier to keep the EMC within an allowable range, the quality of the wiring board (circuit board) is improved, and the burden of designing the wiring board (circuit board) and the like can be reduced.

Moreover, in an embodiment of the present invention, a vehicle display device may include a wiring board that is mounted in a vehicle, a vehicle display device mounted in the vehicle, and a vehicle display control device that is mounted in the vehicle, and supplies to the wiring board an AC signal that is needed for display on the vehicle display device (see FIG. 2A).

As a result of applying the present invention to a vehicle display device, a decrease in the display quality of the vehicle display (including an instrument display, a traffic guidance display, and the like) is suppressed. For example, an accurate and easily viewed vehicle display can be realized.

In addition, in an embodiment of the present invention, the vehicle display device may be an instrument display device that displays information indicating the state of the vehicle.

An instrument display shows important information such as the vehicle speed and engine speed, and is required to present accurate and easily viewed information. As a result of applying the present invention, a decrease in the quality of the instrument display is suppressed, and an accurate and easily viewed instrument display can be realized.

The present invention is not limited to the exemplary embodiments described above, and those skilled in the art will be able to easily modify the exemplary embodiments described above within the scope of the claims.

### REFERENCE SIGNS LIST

10 Ground plane
14 Wiring layer
17 Insulating substrate
19, 29, 30 Return current
21, 23, 27 High-frequency signal (microwave)
42 Ground pattern for electronic component
40a to 40c Through-conductor (through-via)
50 Electronic component
100 Four-layer wiring board
101 Wiring layer of first layer
104, 105 Ground plane of second and third layer
107 Wiring layer of fourth layer
102, 104, 106 Insulating substrate (such as glass epoxy resin)
140 IC
151 Through-conductor structure for VBB
152, 153 Through-conductor structure for differential current signal
160 Electronic component
170 Connector
173 Vehicle display device (instrument display device)
195 Vehicle display control device
CX1, CX2 Parasitic capacitance formed between wiring layer and ground plane

1. A wiring board comprising:
a wiring layer provided on a first surface of an insulating substrate having a predetermined thickness, and a flat shape; and
a ground plane provided on a second surface that opposes the first surface via the insulating substrate; wherein
the wiring layer includes
a signal transmission pattern serving as a transmission path that transmits a high-frequency signal,
a first ground pattern serving as a first ground surface that defines a reference potential in the wiring board, and
a second ground pattern serving as a second ground surface that is DC-isolated from the first ground pattern, and which functions as an AC ground for an AC signal flowing through the signal transmission pattern, the second ground pattern including a ground pattern for an electronic component, the ground pattern for an electronic component being connected to another pole of an electronic component that is mounted as a result of one pole being connected to the signal transmission pattern,
the ground plane is formed with
a first cutout portion, being a cutout portion for the electronic component, which is formed at a position facing the electronic component mounted on the wiring layer via the insulating substrate, and in which a conductor layer constituting the second ground pattern is removed, and
a second cutout portion serving as a slit portion that electrically isolates a first ground plane corresponding to the first ground pattern of the wiring layer and a second ground plane corresponding to the second ground pattern of the wiring layer,
in a transparent plan view as viewed from the first surface side of the insulating substrate, the first and second cutout portions are arranged such that at least a portion is overlapping,
in a transparent plan view as viewed from the first surface side of the insulating substrate, the ground pattern for an electronic component included in the second ground pattern extends in a transmission direction of the AC signal across the second cutout portion serving as the slit portion,
the first ground plane is electrically connected to the ground pattern for an electronic component by a first through-conductor that penetrates through the insulating substrate,
the second ground plane is electrically connected to the ground pattern for an electronic component by a second through-conductor that penetrates through the insulating substrate, and
the first through-conductor, the ground pattern for an electronic component, and the second through-conductor constitute a bypass path that causes a return current, which is generated in the ground pattern in response to the AC signal flowing in the signal transmission path, to flow around the second cutout portion serving as the slit portion.

2. The wiring board according to claim 1, wherein
the electronic component is
a high-value resistor having one pole connected to the signal transmission pattern, and another pole connected to the ground pattern for an electronic component, and that DC-isolates the first and second ground patterns, or
a diode having one pole connected to the signal transmission pattern, and another pole connected to the ground pattern for an electronic component, and that is used to suppress an overcurrent or an overvoltage in the signal transmission pattern.

3. The wiring board according to claim 1, wherein
the AC signal is a differential current signal.

4. The wiring board according to claim 1, wherein
in a transparent plan view as viewed from a first surface side of the insulating substrate,
the first cutout portion, which is a cutout portion for an electronic component, overlaps the second cutout portion and, among ground patterns isolated by the slit portion, a ground pattern on a receiving end side of the high-frequency signal, or
the first cutout portion, which is the cutout portion for an electronic component, overlaps the second cutout portion and, among ground patterns isolated by the slit portion, a ground pattern on a transmitting end side of the high-frequency signal, or
the first cutout portion, which is the cutout portion for an electronic component, overlaps both the second cutout portion and two ground patterns isolated by the slit portion.

5. The wiring board according to claim 1, wherein
in a transparent plan view as viewed from a first surface side of the insulating substrate, the first and second ground patterns oppose each other in parallel via the second cutout portion serving as the slit portion, or
in a transparent plan view as viewed from a first surface side of the insulating substrate, the first and second ground patterns oppose each other and each has a corner portion at a position corresponding to the other via the second cutout portion serving as the slit portion.

6. The wiring board according to claim 1, wherein
the wiring board is a multilayer wiring board formed by laminating a plurality of the insulating substrates having the wiring layer and the ground plane.

7. The wiring board according to claim 1, wherein
the wiring board is a vehicle wiring board that is mounted in a vehicle, and
supplies the AC signal to an in-vehicle display device mounted in the vehicle via the signal transmission pattern.

8. A vehicle display device, comprising:
the wiring board according to claim 1, which is mounted in a vehicle;
a vehicle display device mounted in the vehicle; and
a vehicle display control device that is mounted in the vehicle, and supplies to the wiring board an AC signal that is needed for display on the vehicle display device.

9. The vehicle display device according to claim 8, wherein
the vehicle display device is an instrument display device that displays information indicating a state of the vehicle.
